(19) United States
(12) Patent Application Publication
(10) Pub. No.: US 2006/0144427 A1
(43) Pub. Date: Jul. 6, 2006

(54) Plasma cleansing apparatus that eliminates organic and oxidative contaminant and may effectively dissipate heat and eliminate exhaust gas and integrated system for the same

(76) Inventors: Byung-Joon Chun, Suwon-City (KR); Jong-Sung Park, Suwon-City (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 11/316,706

(22) Filed: Dec. 27, 2005

(30) Foreign Application Priority Data
Dec. 30, 2004 (KR) 10-2004-0116434

(51) Int. Cl. B08B 3/00; H01L 21/306; C23F 1/00

(52) U.S. Cl. 134/61; 156/345.31; 156/345.29

(57) ABSTRACT

A plasma cleansing apparatus that eliminates organic and oxidative contaminant and effectively dissipates heat and eliminates exhaust gas comprises an electrode unit, an exothermic unit, a raw gas ducting unit, a raw gas supply ducting unit, and an air drawing and exhausting unit. The exothermic unit is provided with a raised exothermic plate contacting one side of the electrode unit and with an exothermic wall fitting to the plate for dissipation of the heat of electrode unit. A first gas passageway communicating with the exterior is provided at the top end of the air drawing and exhausting unit, while a second gas passageway communicating with the exterior is provided at the bottom end of the air drawing and exhausting unit; the first gas passageway works with the second gas passageway to form a gas discharge function for heat dissipation, an air drawing function for gas discharge, or the two-in-one function.

### BACKGROUND OF THE INVENTION

1. Field of the Invention

This invention relates to a plasma cleansing apparatus that eliminates organic and oxidative contaminant and may effectively dissipate heat and eliminate exhaust gas and integrated system for the same and particularly to an apparatus that, in the course of plasma purgation, may dissipate the heat of an electrode unit by using a exothermic unit and dissipate and eliminate the heat and exhaust waste of matters to be cleaned and electrode unit by using air drawing and exhausting units.

2. Description of Related Art

In the process of manufacturing of general products, regardless of any fields of production flow, the cleansing extent of the surface of all materials usually has an effect on subsequent works of engineering, such as vacuum evaporation, coating, junction of materials and further greatly on the viscosity and close bonding between different raw materials. Accordingly, cleaning the surface of material is a very important engineering, and a conventional method of cleaning the surface of material is used to clean the surface of material with chemicals. However, the chemicals pollute the environment and the like, so they are restricted.

Thus, in order to solve the problems mentioned above, many innovative methods are currently developed, and among the methods of cleaning the surface of material, a method is adapted that is called a method of plasma in conditions of low temperature and low pressure. In the method of low-pressure plasma for cleanness, purgation is implemented in a vacuum chamber formed in low pressure; in such a method, definitely extra energy is applied to raw gas so that the gas is in the state of plasma and generates gaseous ions, and the activated gas contacts the surface of material and then functions with it so that impurities and contaminants stained on the surface of material may be eliminated.

Although the method of low-pressure plasma for surface cleanness has a quite good effect on purgation, but it is not used widely. In order to produce the plasma, co-operation with a vacuum device is a must for use, so the plasma cannot be formed in the environment of barometric pressure.

Further, there are also many operation methods for constant-pressure plasma, in which a method of silent discharge that is applied to an ozone heating instrument is most widespread and used permanently.

The theorem of silent discharge is apparent as everyone knows, in which in the condition of constant pressure, one side or two sides of a metallic electrode are cut off with an insulator and, after AC high voltage or pulse is applied to the metallic electrode, a discharge of high voltage occurs on a space between two electrodes, thereby the plasma required being generated.

With the plasma generated in the same theorem above mentioned for purgation on the space between the two electrodes, after the matters to be cleaned is kept in place, the purgation is implemented, but the method or purgation is limited to only very thin matters to be cleaned. The above mentioned description is made because the matters to be cleaned are not insulators but electrically conductive metals or semiconductors, the matters will be damaged in the situation of high voltage, thereby the method of cleaning being quite limited.

Further, when the plasma gets out of the surface of material for purgation, due to the constant pressure of plasma as a feature, the plasma will generates ozone that is harmful to human body and threatens staff member in security.

Next, a plasma generation apparatus is set very close to the material, so no consideration in electrodes is taken; however, the consideration in arcing occurring between the material and the electrode is taken because this issue will make the material to be damaged. Furthermore, the plasma generation apparatus is featured with high voltage, so it will electrically shock and endanger the user if not properly operated.

### SUMMARY OF THE INVENTION

For solving a technical problem, according to this invention, a plasma cleansing apparatus that eliminates organic and oxidative contaminant and may effectively dissipate heat and eliminate exhaust gas and integrated system for the same is provided. In this invention, the air drawing and exhausting unit is used to eliminate harmful matters and particles generated in the process of plasma purgation.

For another object of this invention, an exothermic unit is used to dissipate the heat of an electrode unit, and an air drawing and exhausting unit is used to dissipate and eliminate the heat and exhaust waste of matters to be cleaned and the electrode unit.

For a next object of this invention, a plurality of ceramic balls are placed in a temporary raw gas storage unit to make the raw gas to be mixed more evenly, thereby the effect of density of the generated plasma being better.

In order to solve the technical problem, in one of the methods of this invention, the plasma cleansing apparatus that eliminates organic and oxidative contaminant and may effectively dissipate heat and eliminate exhaust gas is provided, comprising the electrode unit, the exothermic unit, a raw gas ducting unit, a raw gas supply ducting unit, and the air drawing and exhausting unit. From the description made above, the electrode unit is provided with a plurality of electrodes in parallel that are spaced at predetermined intervals; the exothermic unit is provided with a raised exothermic plate contacting one side of the electrode unit and with an exothermic wall fitting to the raised exothermic plate; the raw gas ducting unit is formed at one side of the exothermic unit and communicates with one end of a passageway formed between the raised exothermic plate and the exothermic wall to guide the raw material through the exothermic unit; the raw gas supply ducting unit communicates with one end of a passageway formed between the raised exothermic plate and the exothermic wall to receive the raw gas passing through the exothermic unit; and the air drawing and exhausting unit is located at a space separate from the raw gas ducting unit, and a first gas passageway communicating with the exterior is provided at the top end of the air drawing and exhausting unit, while a second gas passageway communicating with the exterior is provided at the bottom end of the air drawing and exhausting unit.

In order to solve the technical problem, in one of the methods of this invention, its integrated system that eliminates organic and oxidative contaminant and may effectively dissipate heat and eliminate exhaust gas comprises a plurality of plasma cleansing facilities that are spaced from each other and arranged at predetermined intervals. By means of combination of the plasma cleansing facilities, different virtues based on users' requests are given. Namely, the drawing and exhausting unit of plasma cleansing unit may give a function of gas drawing or exhaust or two functions of gas drawing and exhaust.

In order to further understand the technical means and effects adopted to achieve the objectives of this invention, please refer to the detailed description and accompanied drawings according to this invention. It is believed that the objectives, features, and points of this invention will be apparent from the description; however, the accompanied drawings are provided for reference and illustration only and not intended to limit the terms or scope of this invention.

### BRIEF DESCRIPTION OF THE DRAWINGS

FIG. 1 is a front sectional view of an atmospheric plasma cleansing facility according to this invention;

FIG. 2 is a lateral sectional view of the atmospheric plasma cleansing facility according to this invention;

FIG. 3 is a top view of the atmospheric plasma cleansing facility according to this invention;

FIG. 4 is a 3D schematic view illustrating a raised exothermic plate of the atmospheric plasma cleansing facility according to this invention;

FIG. 5 is a 3D schematic view illustrating a second gas passageway and a plasma outlet of the atmospheric plasma cleansing facility according to this invention;

FIG. 6 is s sectional schematic view illustrating the integrated system of plasma cleansing facilities according to this invention; and

FIGS. 7 to 12 are sectional schematic views illustrating various embodiments of the integrated system of plasma cleansing facilities according to this invention.

### DETAILED DESCRIPTION OF THE PREFERRED EMBODIMENTS

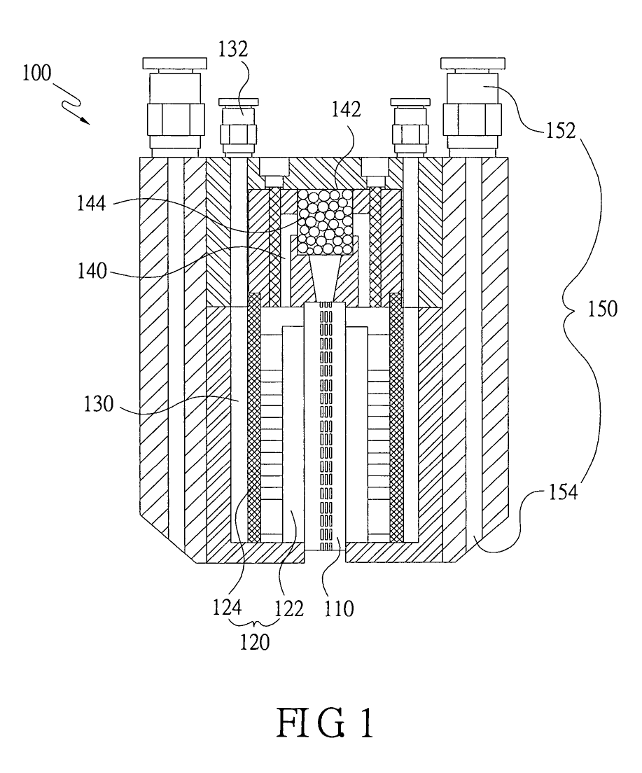

As shown in FIGS. 1 to 3, a plasma cleansing facility (100) according to this invention comprises an electrode unit (110), an exothermic unit (120), a raw gas-ducting unit (130), a raw gas supply ducting unit (140), and an air drawing and exhausting unit (150).

The electrode units (110) are arranged at intervals in the center of the plasma cleansing apparatus (100), and parallel arrangement of the electrode units (110) is most suitable so as to make the plasma heated evenly. When the number of electrodes arranged is odd, such as three electrodes formed, the center of electrode is applied with high voltage and the two sides of electrode is grounded. Further, the power supplied by the electrode is high voltage power supply, so general voltage cannot be directly used. In case of general power, an extra power supply device with a transformer must be provided to change the high voltage power supply.

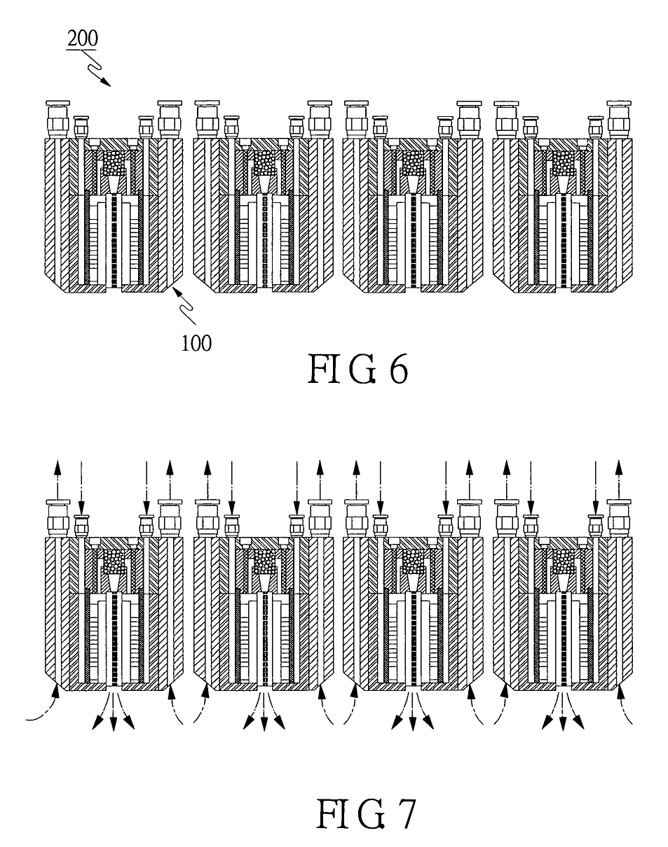

Next, the exothermic unit (120) is structured with a raised exothermic plate (122) and an exothermic wall (124). As shown in FIG. 1, the raised exothermic plate (122) contacts the outside of electrode unit (110); namely, after the raised exothermic plate (122) contacts the electrode unit (110), the quantity of heat generated by the electrode unit (110) is conducted back to the raised exothermic plate (122) for heat dissipation so as to lower the temperature of electrode unit (110). As shown in FIG. 4, the raised exothermic plates (122) used are preferably right exothermic lumps (121) in the shape of right hexahedron and arranged at certain intervals. The allocated space of the raised exothermic plate is mainly used to maximize the contact areas between running gas.

The spaces formed between the exothermic lumps (121) are designed to allow the raw gas to pass through. Additionally, in order to diffuse the raw gas passing through the exothermic lumps (121), the exothermic lumps (121) are preferably set cross so that the raw gas passing through the exothermic lumps (121) spreads evenly because blocked by the cross lumps (121). Especially, the temperature of exothermic lumps (121) increases with its exothermic, and after the raw gas is violently activated, the diffusion of gas is further activated. Raw gas in low temperature supplied from the outside passes through the exothermic lumps (121), so the temperature of exothermic lumps (121) decreases. Thus, the quick cooling of raised exothermic plates (121) is one of the advantages of this invention.

As shown in FIG. 1, the top end of exothermic wall (124) contacts the exothermic lump (121). Same as the exothermic lump (121) in length, the exothermic wall (124) serves as a space through which the raw gas passes after the exothermic wall (124) is separated from the raised exothermic plates (122). The bottom end of exothermic wall (124) is open and communicates with the raw gas-ducting unit (130). The raw gas supplied by the raw gas-ducting unit (130) will be guided to the exothermic (120).

After ducting the outside raw gas, the raw gas-ducting unit (130) supplies it to the exothermic unit (120). Accordingly, the raw gas-ducting unit (130) is located in a room separated from the outside of exothermic unit (120).

A raw gas duct (132) located at the top of raw gas ducting unit (130) is used to guide the raw gas, and after passing through the exothermic unit (120) located below, the raw gas gets out of the raised exothermic plate (122).

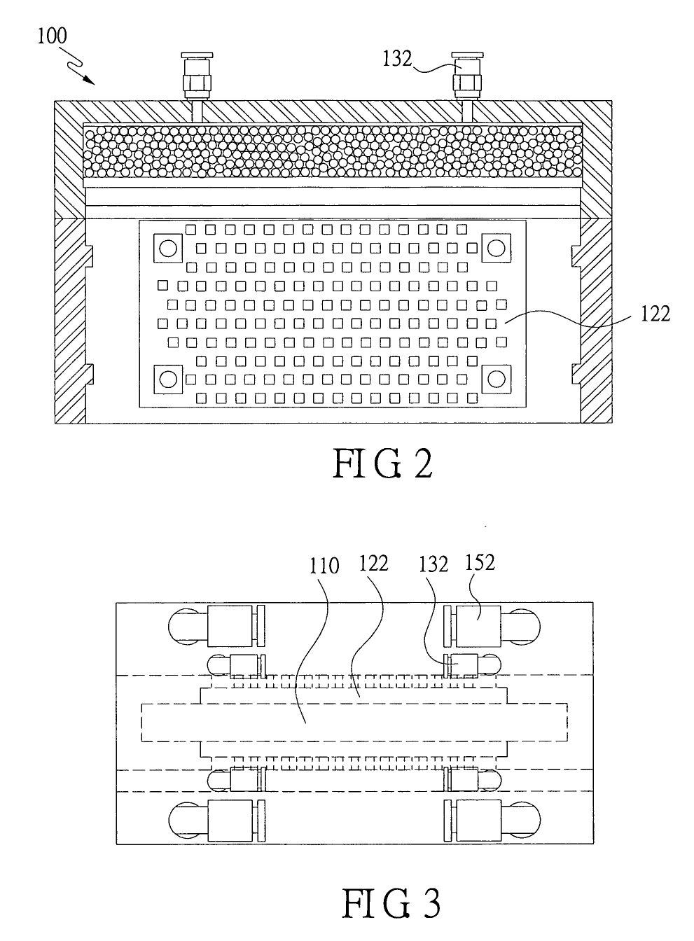

A raw gas supply path (140) connects to the exothermic unit (120) to supply the spread raw gas to the electrode unit (110). The raw gas supply path (140) is at the top of both electrode unit (110) and exothermic unit (120). A temporary raw gas storage unit (142) that temporarily stores the raw gas is provided in the center of raw gas supply path (140), as shown in FIGS. 1 and 2, and the temporary raw gas storage unit (142) is used to evenly spread the raw gas, in which the inside of raw gas supply path (140) is preferably full of ceramic balls (144) that mainly makes the raw gas to be mixed more evenly, thereby the effect of density of the generated plasma being better.

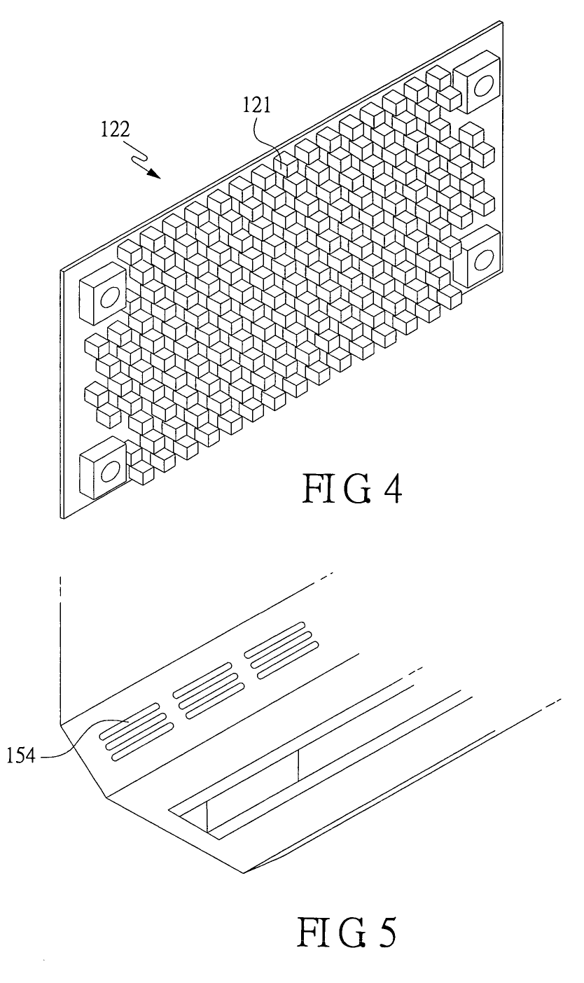

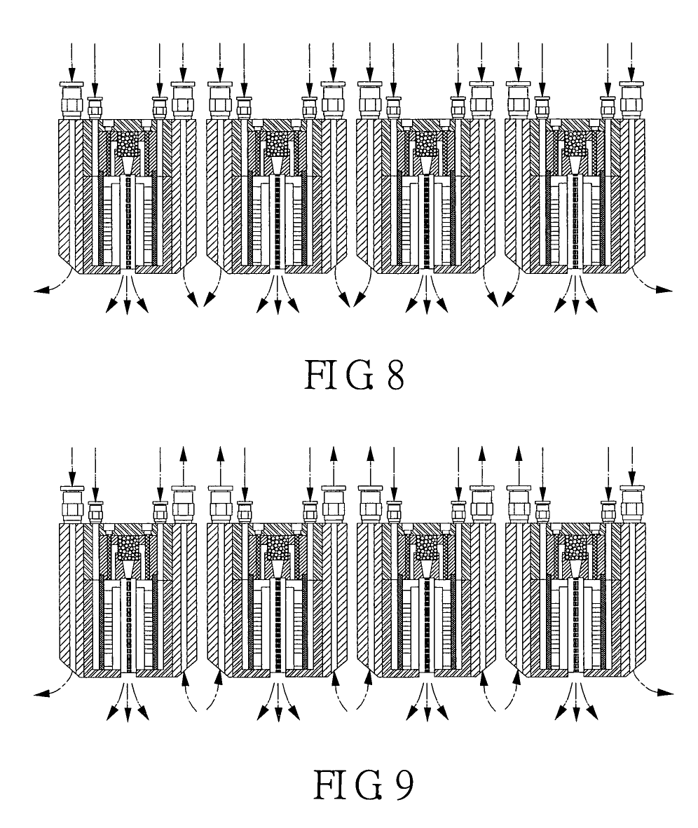

Further, the air drawing and exhausting unit (150) is located as shown in FIG. 1 in accordance with FIG. 3 that separated rooms are provided at the left and right sides of raw gas ducting unit (130). The top end of the air drawing and exhausting unit (150) is a first gas passageway (152) communicating with the outside, while the bottom end of the air drawing and exhausting unit (150) is a second gas passageway (154) communicating with the outside. Namely, the air drawing and exhausting unit (150) is formed with a barrier at the outside of raw gas ducting unit (130) so as to be separate from the raw gas ducting unit (130), and the air drawing and exhausting unit (150) is provided also with a space for cooling air and dirty gas to flow. The first gas passageway (152) is tubular to communicate with the outside, while the second gas passageway (154) is, as shown in FIG. 5, provided with a plurality of spaces at intervals on the wall.

Next, the second gas passageway (154) may be level to ground, or as shown in FIG. 1, the second gas passageway (154) is inclined from ground. Thus, it cannot be impacted to discharge the plasma from the electrode unit (110) for purgation, and in the process of purgation, the formed pollutants even may be effectively discharged.

The first gas passageway (152) comes from the outside of plasma cleansing facility (110) so that the cooling air may be supplied to the air drawing and exhausting unit (150) and the air having absorbed in the air drawing and exhausting unit (150) may be discharged. The second gas passageway (154) depends on the exhaust or absorption function of first gas passageway (152); namely, the gas in the air drawing and exhausting unit (152) may be blown downwards to the outside, or air is absorbed from the outside to the passageway of air drawing and exhausting unit (150). In short, the cooling air supplied from the first gas passageway (152) through the second gas passageway (154) functions in exhaust, while the gas absorbed from the second gas passageway (154) into the first gas passageway (152) functions in air drawing.

When the first gas passageway (152) receives the cooling air supplied from the outside, the cooling air may pass through the second gas passageway (154) and then may be discharged for heat dissipation when the materials are cleaned. Further, in the process of purgation, the pollutants or particles as gas in the space will be harmful to operators, so the function of air drawing of the second pas passageway (154) is used to absorb the pollutants and particles into the passageway of air drawing and exhausting unit (150) and then discharged out of the first gas passageway. Accordingly, meeting users' demands, this invention may blow air to (dissipate heat of) the matters to be cleaned or absorb gas (discharge the pollutants).

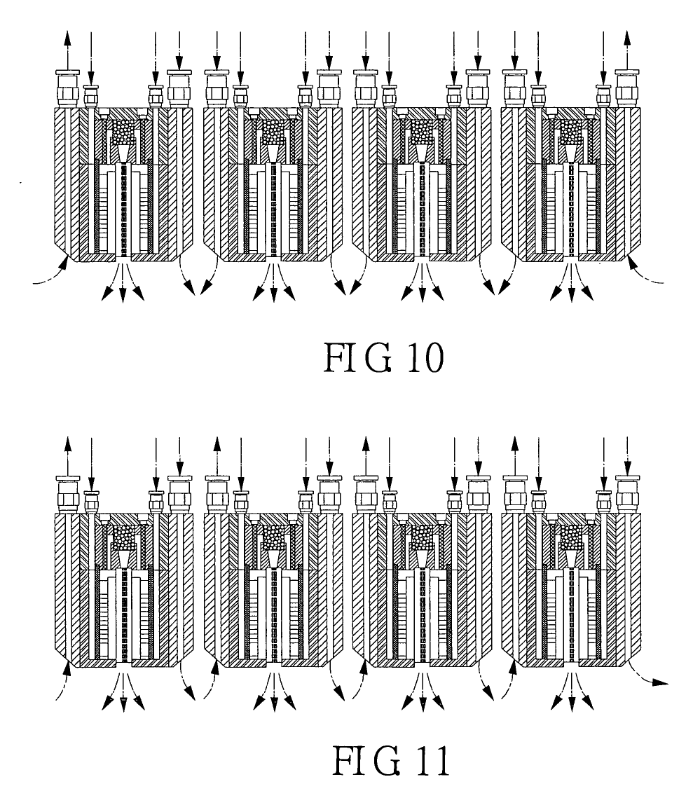

As shown in FIG. 6, the integrated system of plasma cleansing facilities (200) is made up with several plasma cleansing facilities (100) in parallel associated with each other. By this time, the integrated system of plasma cleansing facilities (200) is provided with fixed plasma cleansing facilities (100) (not shown). The plasma cleansing facilities (100) do a cleansing task by using several electrodes in parallel. The integrated system of plasma cleansing facilities (200) may randomly connect to several plasma-cleansing facilities (100) or may use a single plasma cleansing facility (100).

If high power of cleaning to the matters to be cleaned is required, it is determined to increase the number of plasma cleansing facility (100), while If low power of cleaning to the matters to be cleaned is required, it is determined to decrease the number of plasma cleansing facility (100).

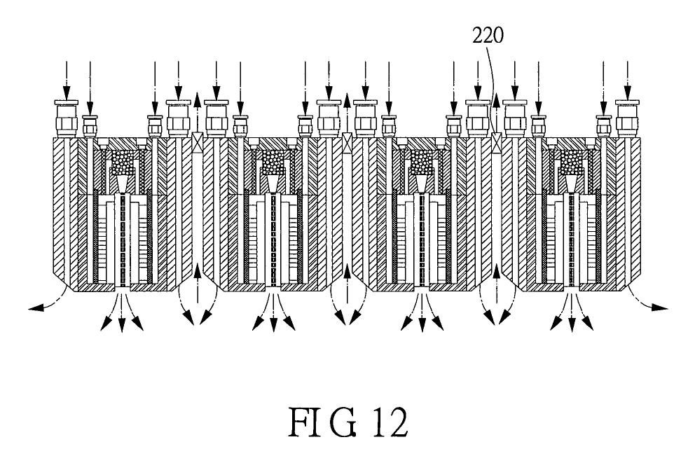

As shown in FIGS. 7 to 12, the integrated system of plasma cleansing facilities (200) is provided with a plurality of plasma cleansing facilities (100) each of which is provided with an air drawing and exhausting unit (150). Thus, each of the plasma cleansing facilities (100) has a cooling function and a function to discharge exhaust generated in the process of plasma treatment. Thus, in order to achieve the virtue of high power of cleaning, according to this invention, the plurality of plasma cleansing facilities (100) may be integrated into a system, and in order to make the plasma cleansing facilities (100) more efficient in the functions of air drawing and exhaustion, each of the air drawing and exhausting units (150) is provided with the function of integration and control. Regarding the function of integration and control, the description is made below.

As shown in FIG. 7, each of several plasma-cleansing facilities (100) is provided with the air drawing and exhausting unit (150) to efficiently discharge the gas. In this case, the pollutants and ozone as harmful matters generated in the progress of cleaning are absorbed and then discharged.

As shown in FIG. 8, each of several plasma-cleansing facilities (100) is provided with the air drawing and exhausting unit (150) to efficiently discharge (blow) the gas. In this case, a powerful cooling is performed on the electrode units and the matters to be cleaned.

As shown in FIG. 9, the most outer air drawing and exhausting units (150) of plasma cleansing facilities (100) merely discharge (blow) the gas, while the remaining the air drawing and exhausting units (150) absorb the gas. As shown in FIG. 10, exactly opposite from that shown in FIG. 9, the most outer air drawing and exhausting units (150) of plasma cleansing facilities (100) merely absorb the gas, while the remaining the air drawing and exhausting units (150) discharge (blow) the gas. It is designed to conduct the cooling function and the air drawing and exhausting function more efficiently.

As shown in FIG. 11, the air drawing and exhausting unit (150) at one side of each plasma cleansing facility (100) serves to absorb the gas, while the air drawing and exhausting unit (150) at the other side serves to discharge (blow) the gas.

As shown in FIG. 12, each of the plurality of plasma cleansing facilities (100) is provided with the air drawing and exhausting unit (150) to discharge (blow) the gas. Next, an air drawing unit (220) is provided between every two plasma-cleansing facilities (100) to absorb the gas.

According to this invention, the raw gas absorbs the heat generated by the exothermic lumps while passing through, thereby the advantage being apparent to effectively reduce the heat.

After the raw gas passes through the exothermic lumps, when the temperature rises, the gas is quite active and the raw gas is more actively spread. Especially, when the raw gas passes through the spaces of exothermic lumps, the gas is spread evenly in the spaces of exothermic units because of the barrier of exothermic lumps. It is characterized in that the raw gas may be given the plasma after the evenly spread gas is supplied to the electrode unit.

However, in the description mentioned above, only the preferred embodiments according to this invention are provided without limit to claims of this invention; all those skilled in the art without exception should include the equivalent changes and modifications as falling within the true scope and spirit of the present invention.

What is claimed is:

1. A plasma cleansing apparatus that eliminates organic and oxidative contaminant and may effectively dissipate heat and eliminate exhaust gas, comprising:
an electrode unit provided with a plurality of electrodes in parallel that are spaced at predetermined intervals;
an exothermic unit provided with a raised exothermic plate contacting one side of the electrode unit and with an exothermic wall fitting to the raised exothermic plate;
a raw gas ducting unit formed at one side of the exothermic unit and communicates with one end of a passageway formed between the raised exothermic plate and the exothermic wall to guide the raw material through the exothermic unit;
a raw gas supply ducting unit communicating with one end of a passageway formed between the raised exothermic plate and the exothermic wall to receive the raw gas passing through the exothermic unit; and
an air drawing and exhausting unit located at a space separate from the raw gas ducting unit, and a first gas passageway that communicates with the exterior being provided at the top end of the air drawing and exhausting unit, while a second gas passageway that communicates with the exterior being provided at the bottom end of the air drawing and exhausting unit.

2. The plasma cleansing apparatus according to claim 1, further comprising a temporary raw gas storage unit communicating with the electrode unit and the raw gas supply ducting unit.

3. The plasma cleansing apparatus according to claim 2, wherein a plurality of ceramic balls are placed in the temporary raw gas storage unit.

4. The plasma cleansing apparatus according to claim 1, wherein cooling gas is absorbed into the first gas passageway and then discharged out of the second gas passageway, thereby a discharge function being formed; or alternatively the gas is absorbed into the second gas passageway and then discharged out of the first gas passageway, thereby the air drawing function being formed.

5. The plasma cleansing apparatus according to claim 4, wherein the air drawing and discharge functions work on the same plasma cleansing facility together or separately.

6. The plasma cleansing apparatus according to claim 1, wherein the vent of second gas passageway is vertical to ground.

7. The plasma cleansing apparatus according to claim 1, wherein the vent of second gas passageway is inclined from ground.

8. The plasma cleansing apparatus according to claim 1, wherein the raised exothermic plate is provided with a plurality of exothermic lumps.

9. An integrated system with plasma cleansing apparatus that eliminates organic and oxidative contaminant and may effectively dissipate heat and eliminate exhaust gas, comprising:
a plurality of plasma cleansing facilities that are spaced from each other and arranged at predetermined intervals, in which each plasma cleansing facility comprises:
an electrode unit provided with a plurality of electrodes in parallel that are spaced at predetermined intervals;
an exothermic unit provided with a raised exothermic plate contacting one side of the electrode unit and with an exothermic wall fitting to the raised exothermic plate;
a raw gas ducting unit formed at one side of the exothermic unit and communicates with one end of a passageway formed between the raised exothermic plate and the exothermic wall to guide the raw material through the exothermic lumps of the exothermic unit;
a raw gas supply ducting unit communicating with one end of a passageway formed between the raised exothermic plate and the exothermic wall to receive the raw gas passing through the exothermic unit; and
an air drawing and exhausting unit located at a space separate from the raw gas ducting unit, and a first gas passageway that communicates with the exterior being provided at the top end of the air drawing and exhausting unit, while a second gas passageway that communicates with the exterior being provided at the bottom end of the air drawing and exhausting unit.

10. The integrated system with plasma cleansing apparatus according to claim 9, wherein the cooling gas is absorbed into all the first gas passageways and then correspondingly discharged out of the second gas passageways to generate the cooled matters to be cleaned and the discharge function of electrode unit after plasma treatment.

11. The integrated system with plasma cleansing apparatus according to claim 9, wherein the waste gas formed in the process of plasma treatment is absorbed into all the second gas passageways and then correspondingly discharged out of the first gas passageways to form a function of absorbing the waste gas.

12. The integrated system with plasma cleansing apparatus according to claim 9, wherein the cooling gas is absorbed into the most outer first gas passageways and then correspondingly discharged out of the second gas passageways to generate the cooled matters to be cleaned and the discharge function of electrode unit after plasma treatment; the waste gas formed in the process of plasma treatment is absorbed into the other second gas passageways and then correspondingly discharged out of the first gas passageways to form a function of absorbing the waste gas.

13. The integrated system with plasma cleansing apparatus according to claim 9, wherein the waste gas formed in the process of plasma treatment is absorbed into the most outer second gas passageway and then correspondingly discharged out of the first gas passageways to form a function of absorbing the waste gas; the cooling gas is absorbed into the remaining first gas passageways and then correspondingly discharged out of the second gas passageways to generate the cooled matters to be cleaned and the discharge function of electrode unit after plasma treatment.

14. The integrated system with plasma cleansing apparatus according to claim 9, wherein the cooling gas is absorbed into one of the first gas passageways of each atmospheric plasma cleansing facility and then correspondingly discharged out of one of the second gas passageways to generate the cooled matters to be cleaned and the discharge function of electrode unit after plasma treatment; next, the waste gas formed in the process of plasma treatment is absorbed into another second gas passageway of each atmospheric plasma cleansing facility and then correspondingly discharged out of another first gas passageways to form a function of absorbing the waste gas.

15. The integrated system with plasma cleansing apparatus according to claim 9, wherein an air drawing unit is provided between every two plasma cleansing facilities.
